(19) United States
(12) Patent Application Publication
(10) Pub. No.: US 2020/0024741 A1
(43) Pub. Date: Jan. 23, 2020

(54) MATERIAL DEPOSITION IN A MAGNETIC FIELD

(71) Applicant: Coventry University, Coventry (GB)

(72) Inventors: Andrew Cobley, Coventry West Midlands (GB); Sofya Danilova, Coventry West Midlands (GB)

(73) Assignee: Coventry University, Coventry (GB)

(21) Appl. No.: 16/066,988

(22) PCT Filed: Jan. 5, 2017
(86) PCT No.: PCT/GB2017/050014

§ 371 Date: Jun. 28, 2018

(30) Foreign Application Priority Data
Jan. 6, 2016 (GB) 1600214.9

(51) Int. Cl. C23C 18/16; C23C 18/18; C23C 18/30; H05K 1/18; H05K 1/09; H05K 3/18

(52) U.S. Cl. CPC C23C 18/1673; H05K 2203/104; C23C 18/1639; C23C 18/1608; C23C 18/1831; C23C 18/30; C23C 18/1834; H05K 1/181; H05K 1/09; H05K 3/182; H05K 2201/083; H05K 2203/0716; H05K 2203/072; H05K 2201/0257; H05K 2201/0218; C23C 18/1603

(57) ABSTRACT

The present invention provides for depositing a desired pattern (31) of magnetic material (30) on a non-magnetic substrate (20). Control of the deposition pattern (31) is achieved by use of a magnetised template (10) shaped to correspond to the desired deposition pattern. In use, the template (10) is placed behind the substrate (20). Subsequently, the front surface of the substrate (20) is exposed to a solution containing the magnetic material (30) to be deposited. The magnetic material (30) is attracted to the magnetised template (10) and consequently is deposited in a pattern (31) covering areas corresponding to the shape of the template (10).

### TECHNICAL FIELD OF THE INVENTION

The present invention relates to material deposition in a magnetic field and in particular to controlled deposition of material on a non-conductive or dielectric substrate in a desired pattern using a magnetised template.

### BACKGROUND TO THE INVENTION

Many electronic devices require the provision of a pattern of conducting material on a non-conducting substrate. Typically, the provision of the conducting pattern is achieved using photolithography. In some instances, this involves a subtractive process whereby the full surface of the substrate is covered by a conductive layer and a photoresist layer. Selective exposure of the photoresist and etching can then be used to leave only a desired pattern of conductive material upon the substrate. As this subtractive process results in a significant amount of waste of conductive material, it is also known to use an additive process. In such cases, a photoresist layer is provided over the full surface of the substrate and is selectively exposed and removed from areas which are desired to be conductive. Subsequently, the substrate is immersed in a chemical bath enabling a catalyst to be laid down in the areas desired to be conductive. A conductive material can then be deposited upon the catalysed areas and the remaining photoresist can be stripped to leave the desired conductive pattern. Both variations on this method of manufacture are a relatively complex multi-step processes which consume chemicals and require expensive equipment in clean and yellow rooms.

It is also known to deposit a pattern of conductive material on a substrate using electroless plating. In such processes, a pattern of catalytic material must be provided on the surface of the substrate corresponding to the desired pattern of conductive material. The substrate is then immersed in a solution comprising ions of the material to be deposited. Subsequently, the ions of the material to be deposited are deposited on the catalysed areas of the substrate. Whilst this process avoids some of the issues of waste described above, it is still necessary to deposit a pattern of catalytic material on the substrate which does involve many of the same problems.

It is therefore an object of the present invention to provide a method of depositing material on a non-conductive substrate that overcomes or alleviates at least some of the above issues.

### SUMMARY OF THE INVENTION

According to a first aspect of the present invention there is provided a method of selectively depositing a desired pattern of a catalytic material on a front surface of a non-conductive substrate, the method comprising the steps of: providing a magnetised template corresponding to the pattern to be deposited; positioning the template behind the substrate; and exposing at least the front surface of the substrate to one or more solutions containing magnetic catalytic material or containing magnetic material and catalytic material to be deposited.

In this manner the magnetic material in solution is either drawn towards or repelled from the areas of the substrate backed by the magnetised template (depending upon whether the magnetic material is respectively paramagnetic or diamagnetic). In the present invention, use of the term magnetic material should be considered to encompass both diamagnetic and paramagnetic materials. Accordingly, a pattern of the magnetic material is deposited corresponding to the template is reproduced on the substrate. For the sake of clarity, in the present application a deposition pattern can be considered to correspond to the template either positively (the material is deposited in a pattern matching the template) or negatively, (the material is excluded from deposition in a pattern matching the template). This therefore enables a desired deposition pattern to be laid down on a substrate directly (where the catalytic material is also a magnetic material) or indirectly (by blocking deposition of the catalytic material where the catalytic material is not magnetic and a magnetic material is also deposited). In either case, this is a simple process with minimal waste and a reusable template.

In one set of embodiments, the catalytic material is non-magnetic and the magnetic material comprises magnetic blocker particles. In such embodiments, the magnetic blocker particles are selectively deposited on the substrate in a pattern corresponding to the template. In particular, such particles may comprise nanoparticles or microparticles. As discussed above, the corresponding pattern may be positive or negative depending on whether the magnetic blocker particles exhibit paramagnetic or diamagnetic behaviour. As a result of the deposition of the magnetic blocker particles, deposition of the catalytic material takes place only in areas of the substrate where the magnetic blocker particles are not deposited.

In some such embodiments, the magnetic blocker particles and catalytic material may be contained in the same solution. In other such embodiments, the substrate may be first exposed to a solution comprising magnetic blocker particles and then is exposed to a solution containing catalytic material.

In such embodiments, the method may comprise the additional step of removing the magnetic blocker particles. This step may take place after deposition of the catalytic material. This step may be achieved by washing, rinsing in water, spraying or by re-immersion in a pre-treatment solution or the like. Re-immersion beneficially enables the ‘capture’ of the excess particles for reuse.

Magnetic blocker particles may be formed from any suitable substance exhibiting magnetic properties including but not limited to Iron, Nickel, Cobalt or compounds containing these elements or alloys containing these elements or materials containing these elements or the like.

In other embodiments, the catalytic material may comprise ions, colloid or particles of a catalytic material that exhibit magnetic properties. In particular, such particles may comprise nanoparticles or microparticles. In this context, the skilled man should appreciate that the ion of a catalytic material can have different magnetic properties to a nanoparticle containing the same material or indeed a colloid containing said material. In this manner, the method may be implemented using materials that only exhibit magnetic properties in a suitable solution or when contained in suitable microparticles, nanoparticles or colloids.

In some embodiments, the nanoparticles may comprise both catalytic material and magnetic material. In one example, the particles may comprise a core of magnetic material provided with an outer layer, shell or coating of catalytic material. In another example, the particles may comprise Janus particles having one end formed of magnetic material and a second end formed of catalytic material. Other composite or alloy particles that comprise some part of a catalytic and another part of a magnetic material might also be used. In each such example, the magnetic material may comprise any suitable substance exhibiting magnetic properties including but not limited to Iron, Nickel, Cobalt or compounds containing these elements or alloys containing these elements or materials containing these elements or the like.

The catalytic material may comprise any suitable material for catalysing an electroless plating process. The catalytic material is preferably a metal. In such embodiments, the catalytic material may comprise, but is not limited to: Palladium, Gold, Silver, Copper, Nickel, Tin or Platinum, Cobalt, Iron or Zinc or alloys comprising said substances. In alternative embodiments the catalytic material may be carbon or any other material which is catalytic towards electroless plating.

Depending on whether the catalytic ion, colloid or nanoparticle is diamagnetic or paramagnetic the catalytic material in the catalytic solution is either drawn towards or repelled by the magnetised template. Where the catalytic material is paramagnetic, the deposition of the catalytic material positively corresponds to the shape of the magnetised template; where the catalytic material is diamagnetic, the deposition of the catalytic material negatively corresponds to the shape of the magnetised template or is deposited in areas away from the magnetic field.

The non-conducting substrate may be a dielectric. The non-conducting substrate may be formed from a polymer, plastic, ceramic, silicon, glass or the like. In some embodiments, the non-conducting substrate may comprise a fabric or textile. In such cases, the fabric or textile may be formed from fibres of any suitable material including but not limited to polymer, plastic, ceramic, silicon, glass or the like. In this manner, the present method may facilitate the manufacture of wearable electronic devices.

In some embodiments, the front surface of the substrate may be polished or smoothed before exposure to the solution. This can help encourage the movement of the magnetic material across the front surface of the substrate to the desired areas,

The method may comprise the further step of selectively depositing a desired secondary material on the deposited catalyst pattern. The secondary material can be deposited by any suitable method. In a preferred embodiment, the secondary material can be deposited by use of electroless plating techniques. Preferably, the secondary material may comprise: Copper, Nickel or Cobalt or alloys (in particular Nickel-Phosphorus or Nickel-Boron) or composites comprising Copper, Nickel or Cobalt. In this context, composites may comprise materials where particles are co-deposited in the Copper, Nickel or Cobalt metal matrix. In other embodiments, the secondary material may comprise Palladium, Silver, Tin, Zinc or Platinum or Gold or alloys or composites containing such materials.

The magnetised template is preferably formed from a suitable ferromagnetic substance. In particular, the magnetised template may comprise Iron or may comprise alloys or compounds containing Iron. In other embodiments, the magnetised template may be formed from Cobalt, Nickel, or may comprise alloys or compounds containing Cobalt or Nickel.

The method may be applied to the manufacture of electronic devices whereby there is a requirement to deposit conductive circuitry on a non-conductive or dielectric substrate. The technique will be particularly useful where the non-conductive substrate is thin (less than 1 mm) e.g. in printed electronics, RFID tags, sensors, semiconductor devices etc. In particular, the device may comprise a printed circuit board, a moulded interconnect device, a waveguide, an optoelectronic device, a metal oxide semiconductor (CMOS) device, photovoltaics or coatings used for EMI/RFI Shielding, RF and Microwave Housings, IR heat barriers, vapour barriers, Microwave Susceptors, memory discs or the like. In other implementations, the device may comprise a non-electronic device such as bathroom fittings, printing rollers, spray nozzles, microneedles, anti-microbial coatings or decorative finishes that are purely aesthetic or are used for artistic creations such as sculptures.

According to a second aspect of the present invention there is provided an electronic device comprising one or more electrical components mounted on a non-conductive substrate, the electrical components connected together via a conducting pattern of material wherein the electrical device is manufactured using the method of the first aspect of the present invention.

The electronic device of the second aspect of the present invention may incorporate any or all features of the first aspect of the present invention, as desired or as appropriate.

According to a third aspect of the present invention there is provided a magnetised template for use in the method of the first aspect of the present invention, the magnetised template comprising a ferromagnetic substance, the substance shaped so as to correspond to the pattern to be deposited on the substrate.

The magnetised template of the third aspect of the present invention may incorporate any or all of the features of the first or second aspects of the present invention, as desired or as appropriate.

### DETAILED DESCRIPTION OF THE INVENTION

In order that the invention may be more clearly understood an embodiment thereof will now be described, by way of example only, with reference to the accompanying drawings, of which:

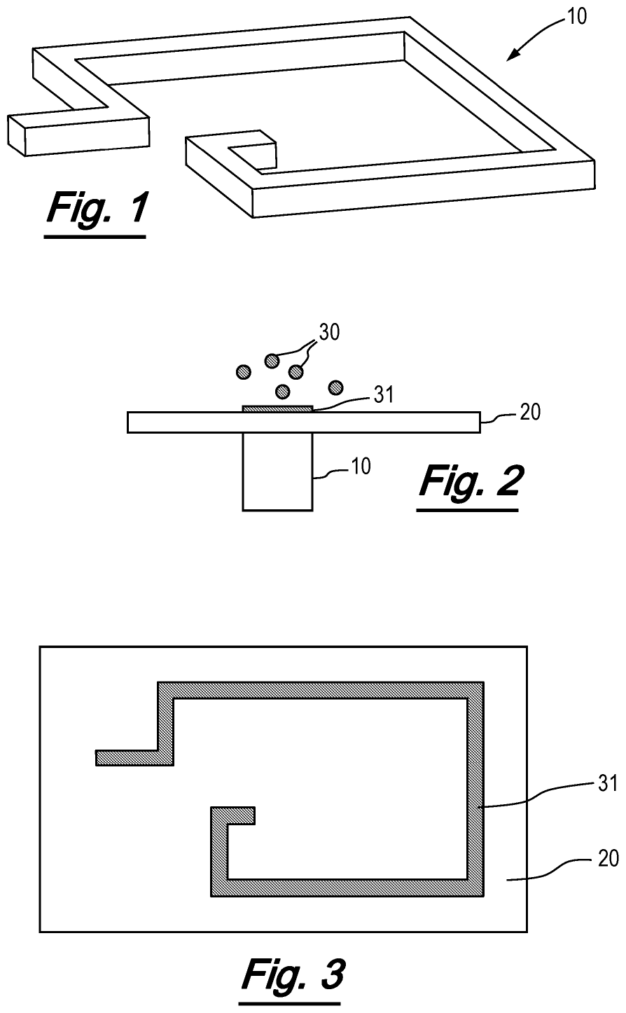

FIG. 1 is a schematic illustration of an exemplary magnetised template according to the present invention;

FIG. 2 is a schematic cross-sectional illustration of the deposition of a magnetic catalytic material on to a substrate using the magnetised template of FIG. 1 according to the method of the present invention;

FIG. 3 is a schematic illustration of the resultant pattern of material deposited on the substrate of FIG. 2 according to the method of the present invention;

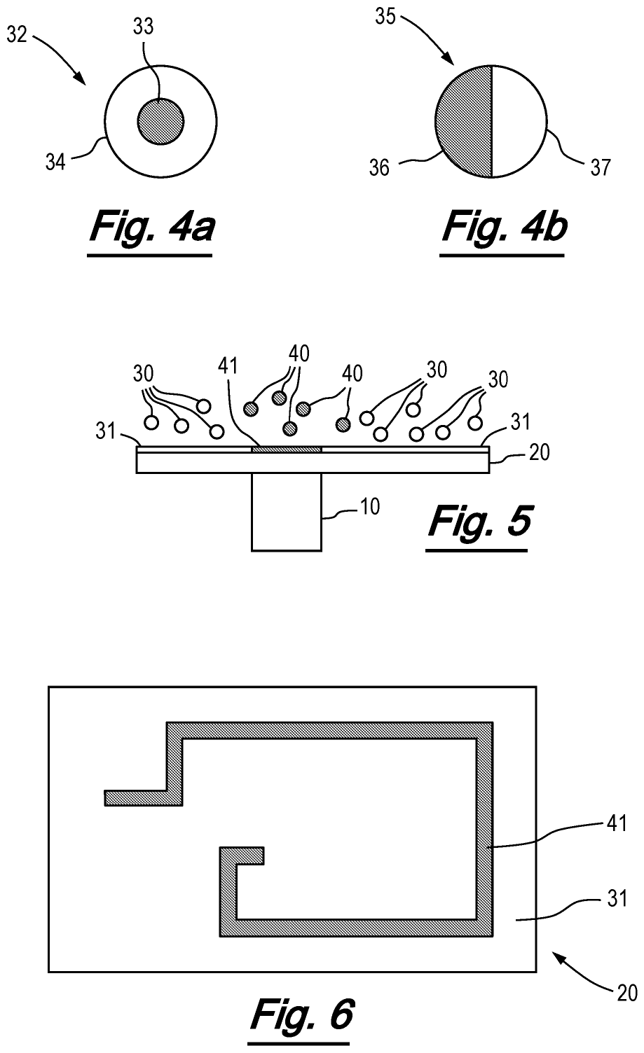

FIG. 4a is a schematic illustration of a type of compound particle that may be used to implement the method of the present invention;

FIG. 4b is a schematic illustration of another type of compound particle that may be used to implement the method of the present invention;

FIG. 5 is a schematic cross-sectional illustration of the deposition of a magnetic material and a catalytic material on to a substrate using the magnetised template of FIG. 1 according to the method of the present invention; and

FIG. 6 is a schematic illustration of the resultant pattern of material deposited on the substrate of FIG. 5 according to the method of the present invention.

The present invention provides for depositing a desired pattern 31 of catalytic material 30 on a non-conductive substrate 20. Typically, the substrate 20 is formed from a polymer, plastic, ceramic, silicon, glass or the like.

Control of the deposition pattern 31 is achieved by use of a magnetised template 10. Turning now to FIG. 1, an example of a magnetised template 10 is provided. The template 10 is formed from a ferromagnetic material, such as iron, and is shaped to correspond to the desired deposition pattern.

In use, the template 10 is placed behind the substrate 20, as shown in FIG. 2. In some embodiments, a further magnet (not shown) may be placed behind the template 10 to ensure it is magnetised. Subsequently, the front surface of the substrate 20 is exposed to a solution containing the magnetic catalytic material 30 to be deposited. The catalytic material 30 (if paramagnetic) is attracted to the magnetic template 10 and consequently is deposited in a pattern 31 covering areas matching the shape of the template 10 as is shown in FIG. 3. The skilled man will appreciate that if the catalytic material 30 is diamagnetic, it is repelled from the magnetic template 10 and consequently is deposited in a pattern 31 covering areas except those matching the shape of the template 10.

In order to encourage the movement of the magnetic material 30 under the magnetic field across the front surface of the substrate 20 to the desired areas, the front surface of the substrate may be polished or smoothed before exposure to the solution.

Where the catalytic material 30 is not inherently magnetic, it may be provided in the form of particles, typically nanoparticles, combining both catalytic material and magnetic material. One example of such a particle 32 is shown in FIG. 4a. In this example, the particle 32 comprises a core 33 of magnetic material (such as Iron Oxide or the like) and an outer layer 33 of catalytic material. Another example of a particle 35 is the Janus particle shown in FIG. 4b. The Janus particle 35 comprises a first face 36 formed from magnetic material (such as Iron Oxide or the like) and a second face 37 formed from catalytic material.

In alternative embodiments where the catalytic material 30 is not inherently magnetic, magnetic blocker particles 40, typically microparticles, may be added to the solution. As is illustrated in FIG. 5, the magnetic material 40 (if paramagnetic) is attracted to the magnetic template 10 and consequently is deposited in a pattern 41 covering areas matching the shape of the template 10 as is shown in FIG. 6. The catalytic material 30 is consequently deposited in a pattern 31 covering areas except those matching the shape of the template 10. The skilled man will of course appreciate that if the magnetic material 40 were diamagnetic, the magnetic material 40 would instead be repelled by the template 10 and the deposition patterns 41, 31 of magnetic material 40 and catalytic material 30 would be reversed.

In embodiments using both catalytic material 30 and magnetic material 40, the materials 30, 40 may be applied in a single solution. Alternatively, a solution comprising the magnetic material 40 may be applied before the application of a solution comprising catalytic material 30. In either case, the method may involve removing the magnetic blocker particles 40 after deposition of the catalytic material 30. Typically this can be achieved by a suitable washing process.

In some instances, the catalytic material 30 is a catalyst for a subsequent process. In particular, the catalytic material 30 may be Palladium, Gold, Silver, Copper, Tin, Carbon, Iron, Cobalt, Zinc, Platinum or any other material which is catalytic for electroless plating. The catalytic material may also comprise a colloids, alloys, nanoparticles or microparticles formed from such materials. Subsequently, the method may include the further step of using an electroless plating method to deposit secondary material such as Copper, Nickel or Cobalt over the catalysed areas. In this manner, the present invention provides a ready process for forming a conductive pattern on a non-conductive substrate which minimises waste material.

The above embodiment is described by way of example only. Many variations are possible without departing from the scope of the invention as defined in the appended claims.

1. A method of selectively depositing a desired pattern of a material on a front surface of a non-conductive substrate, the method comprising the steps of: providing a magnetised template corresponding to the pattern to be deposited; positioning the template behind the substrate; and exposing at least the front surface of the substrate to one or more solutions containing magnetic catalytic material to be deposited and selectively depositing a desired secondary material on the deposited catalyst pattern.

2-5. (canceled)

6. A method as claimed in claim 1 wherein the catalytic material comprise ions, colloid or nanoparticles of a catalytic material that exhibits magnetic properties.

7. A method as claimed in claim 6 wherein the nanoparticles comprise both catalytic material and magnetic material.

8. A method as claimed in claim 7 wherein the nanoparticles comprise a core of magnetic material provided with an outer layer, shell or coating of catalytic material.

9. A method as claimed in claim 7 wherein the nanoparticles comprise Janus particles having one end formed of magnetic material and a second end formed of catalytic material.

10. A method as claimed in claim 1 wherein the catalytic material comprises a material for catalysing an electroless plating process.

11. A method as claimed in claim 1 wherein the catalytic material is Carbon, Palladium, Gold, Silver, Copper, Nickel, Tin, Iron, Cobalt, Zinc or Platinum or alloys comprising said substances.

12. A method as claimed in claim 1 wherein the non-conducting substrate is a dielectric.

13. A method as claimed in claim 12 wherein the substrate is formed from a polymer, plastic, ceramic, silicon, glass, fabric or textile.

14. A method as claimed in claim 1 wherein the front surface of the substrate is polished or smoothed before exposure to the solution.

15. (canceled)

16. A method as claimed in claim 15 wherein the secondary material is deposited by use of electroless plating techniques.

17. A method as claimed in claim 15 wherein the secondary material is: Copper, Nickel or Cobalt or alloys or composites comprising Copper, Nickel or Cobalt or wherein the secondary material is: Palladium, Silver, Tin, Zinc or Platinum or Gold or alloys or composites containing such materials.

18. A method as claimed in claim 1 wherein the magnetised template is formed from a ferromagnetic substance.

19. A method as claimed in claim 1 wherein the method is applied to the manufacture of electronic devices.

20. An electronic device comprising one or more electrical components mounted on a non-magnetic substrate, the electrical components connected together via a conducting pattern of magnetic material wherein the electrical device is manufactured using the method of claim 1.

21. (canceled)
